(19) United States
(12) Patent Application Publication
(10) Pub. No.: US 2025/0107148 A1
(43) Pub. Date: Mar. 27, 2025

(54) THIN FILM TRANSISTOR

(71) Applicant: AUO Corporation, Hsinchu (TW)

(72) Inventors: Ssu-Hui Lu, Hsinchu (TW); Wen-Ching Sung, Hsinchu (TW); Hsiu-Chun Hsieh, Hsinchu (TW)

(73) Assignee: AUO Corporation, Hsinchu (TW)

(21) Appl. No.: 18/544,318

(22) Filed: Dec. 18, 2023

(30) Foreign Application Priority Data
Sep. 27, 2023 (TW) 112136992

(51) Int. Cl. H01L 29/786; H01L 29/417

(52) U.S. Cl. CPC H10D 30/6715; H10D 30/6729

(57) ABSTRACT

A thin film transistor includes a semiconductor layer, a gate insulating layer and a gate. The semiconductor layer has a first heavily doped region, a first lightly doped region, a first intrinsic region, a second lightly doped region, a second intrinsic region, a third lightly doped region and a second heavily doped region. A first conductive pattern of the gate has a first portion, a second portion and an opening portion. The first portion of the first conductive pattern shields the first intrinsic region. The second portion of the first conductive pattern shields the second intrinsic region. The opening portion of the first conductive pattern overlaps the second lightly doped region. A second conductive pattern of the gate covers the first conductive pattern. The second conductive pattern has a first portion and a second portion that are located on two opposite sides of the first conductive pattern.

### CROSS-REFERENCE TO RELATED APPLICATION

This application claims the priority benefit of Taiwan application serial no. 112136992, filed on Sep. 27, 2023. The entirety of the above-mentioned patent application is hereby incorporated by reference herein and made a part of this specification.

### BACKGROUND

### Technical Field

The invention relates to an electronic component, and more particularly, to a thin film transistor.

### Description of Related Art

A light-emitting diode (LED) display panel includes an active device substrate and a plurality of LED elements transferred to the active device substrate. Inheriting characteristics of LEDs, the LED display panel has advantages of power saving, high efficiency, high brightness, fast response time, etc. In addition, compared with an organic LED display panel, the LED display panel further have advantages of easy color adjustment, long luminous life, no image imprinting, etc. Therefore, the LED display panel is regarded as a display technology of a next generation. Generally, the LED element need to be driven by a thin film transistor on the active device substrate. The thin film transistor used to drive the LED element must be able to provide a large turn-on current and meet a requirement of low power consumption.

### SUMMARY

The invention provides a thin film transistor with a large turn-on current and low power consumption.

The invention provides a thin film transistor including a semiconductor layer, a gate insulating layer, a gate, a first terminal and a second terminal. The semiconductor layer has a first heavily doped region, a first lightly doped region, a first intrinsic region, a second lightly doped region, a second intrinsic region, a third lightly doped region and a second heavily doped region arranged in sequence. The gate insulating layer is disposed on the semiconductor layer. The gate includes a first conductive pattern and a second conductive pattern. The first conductive pattern is disposed on the gate insulating layer, and has a first portion, a second portion and an opening portion. The first portion of the first conductive pattern shields the first intrinsic region. The second portion of the first conductive pattern shields the second intrinsic region. The opening portion of the first conductive pattern overlaps the second lightly doped region. The second conductive pattern covers the first conductive pattern. The second conductive pattern has a first portion and a second portion extending to an outside of the first conductive pattern and respectively located on two opposite sides of the first conductive pattern. The first portion and the second portion of the second conductive pattern respectively shield the first lightly doped region and the third lightly doped region. The first terminal and the second terminal are respectively electrically connected to the first heavily doped region and the second heavily doped region of the semiconductor layer.

### BRIEF DESCRIPTION OF THE DRAWINGS

FIG. 1A to FIG. 1E are schematic cross-sectional views of a manufacturing process of a thin film transistor according to an embodiment of the invention.

FIG. 2 is a schematic top view of a thin film transistor according to an embodiment of the invention.

FIG. 3 is a schematic cross-sectional view of a thin film transistor of a comparative example.

FIG. 4 illustrates relationship curves of a gate voltage and a drain current of a thin film transistor of an embodiment of the invention and a thin film transistor of a comparative example.

FIG. 5 illustrates relationship curves of a drain voltage and a drain current of a thin film transistor of an embodiment of the invention and a thin film transistor of a comparative example.

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

It will be understood that when a component such as a layer, a film, a region, or a substrate is referred to be “on” or “connected to” another component, it may be directly on or connected to the other another component, or intermediate components may also exist there between. Comparatively, when a component is referred to be “directly on” or “directly connected” to another, none other intermediate component exits there between. As used herein, the “connection” may refer to physical and/or electrical connection. Furthermore, “electrical connection” or “coupling” of two components may refer to that other components may exist between the two components.

The terms “about”, “substantial” or “approximate” used herein include the related value and an average within an acceptable deviation range for a specific value determined by those skilled in the art, considering a discussed measurement and a specific number of errors related to the measurement (i.e. a limitation of a measuring system). For example, “about” may represent a range within one or a plurality of standard deviations of the related value, or within +30%, +20%, +10%, +5%. Moreover, the “about”, “substantially”, or “approximate” used herein may be a more acceptable deviation range or standard deviation based on optical properties, etching properties, or other properties, and not one standard deviation may be applied to all properties.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

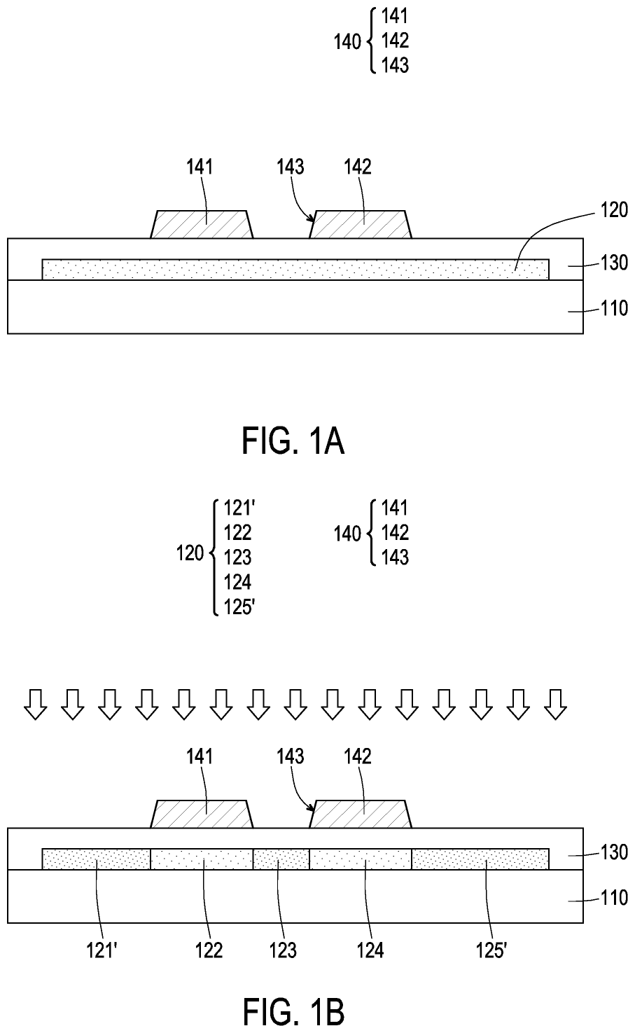

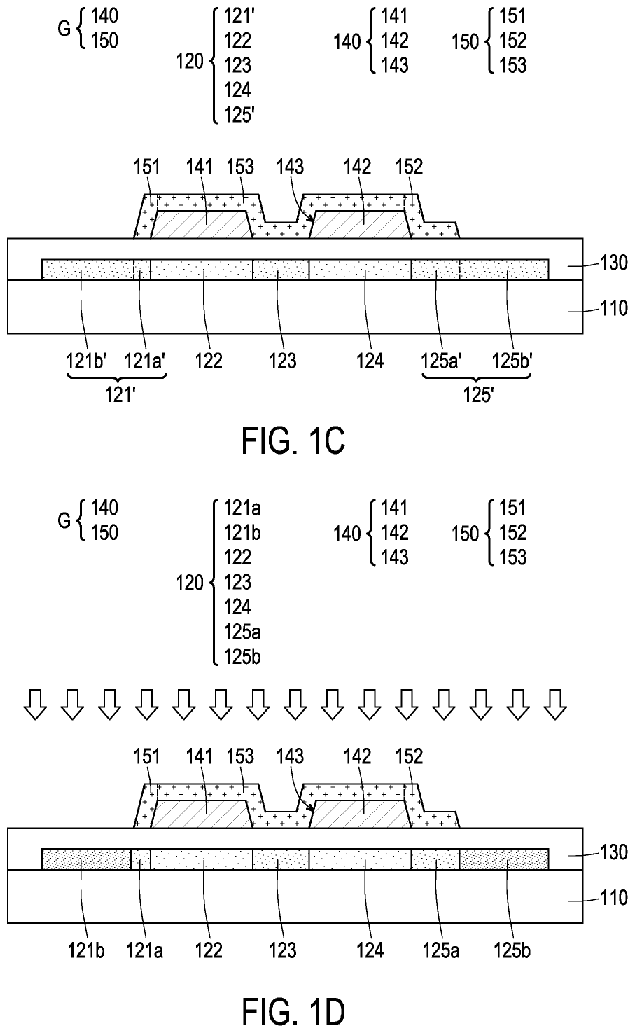

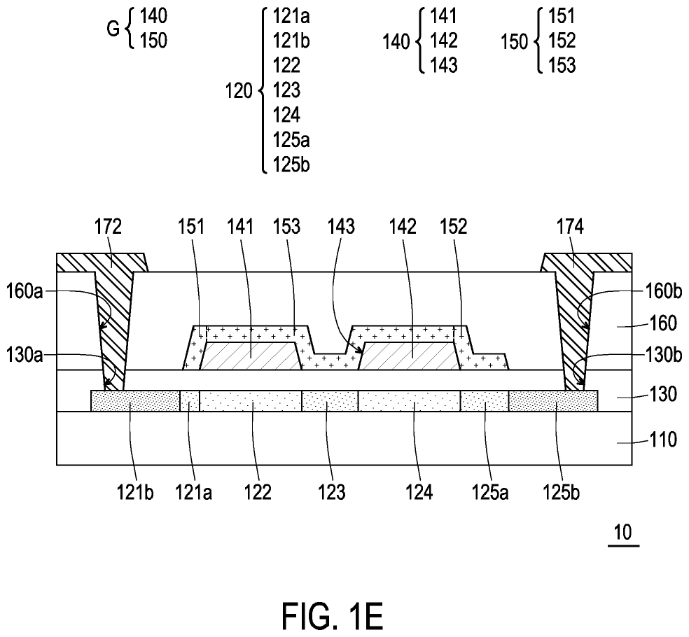

FIG. 1A to FIG. 1E are schematic cross-sectional views of a manufacturing process of a thin film transistor according to an embodiment of the invention.

Referring to FIG. 1A, first, a semiconductor layer 120 is formed on a substrate 110. In an embodiment, a material of the substrate 110 is, for example, glass. However, the invention is not limited thereto. In other embodiments, the material of the substrate 110 may also be quartz, organic polymer, or other applicable materials. In an embodiment, a material of the semiconductor layer 120 is, for example, polysilicon. However, the invention is not limited thereto. In other embodiments, the material of the semiconductor layer 120 may also be amorphous silicon, microcrystalline silicon, single crystal silicon, an organic semiconductor material, an oxide semiconductor material, or combinations thereof.

Then, a gate insulating layer 130 is formed on the substrate 110 to cover the semiconductor layer 120. In an embodiment, a material of the gate insulating layer 130 may be an inorganic material (such as silicon oxide, silicon nitride, silicon oxynitride, or a stacked layer of at least two of the above materials), an organic material, or a combination thereof.

Then, a first conductive pattern 140 is formed on the gate insulating layer 130. The first conductive pattern 140 has a first portion 141, a second portion 142 and an opening portion 143, wherein the first portion 141 and the second portion 142 are separated by the opening portion 143. In an embodiment, the first conductive pattern 140 may be made of a metal material. However, the invention is not limited thereto, according to other embodiments, the first conductive pattern 140 may also be made of other conductive materials (for example, alloys, nitrides of metal materials, oxides of metal materials, oxynitrides of metal materials, or stacked layers of metal materials and other conductive materials).

Referring to FIG. 1A and FIG. 1B, a lightly doped process is performed on the semiconductor layer 120 by using the first conductive pattern 140 as a mask, so that a lightly doped region 121′, a first intrinsic region 122, a second lightly doped region 123, a second intrinsic region 124 and a lightly doped region 125′ are formed in the semiconductor layer 120, where the first intrinsic region 122 and the second intrinsic region 124 are undoped regions. The first intrinsic region 122, the second lightly doped region 123, and the second intrinsic region 124 are respectively overlapped with the first portion 141, the opening portion 143, and the second portion 142 of the first conductive pattern 140. The lightly doped region 121′ and the lightly doped region 125′ are respectively located on two opposite sides of the first conductive pattern 140, and are adjacent to the first intrinsic region 122 and the second intrinsic region 124 respectively.

Referring to FIG. 1B and FIG. 1C, a second conductive pattern 150 is then formed on the gate insulating layer 130, where the second conductive pattern 150 covers and is electrically connected to the first conductive pattern 140. The first conductive pattern 140 and the second conductive pattern 150 form a gate G. The second conductive pattern 150 includes a first portion 151, a second portion 152 and a third portion 153, where the first portion 151 and the second portion 152 extend to the outside of the first conductive pattern 140 and are respectively located at two opposite sides of the first conductive pattern 140, and the third portion 153 covers the first portion 141, the second portion 142 and the opening portion 143 of the first conductive pattern 140. The lightly doped region 121′ may be divided into two parts 121a′ and 121b′, where one part 121a′ is shielded by the first portion 151 of the second conductive pattern 150 extending to the outside of the first conductive pattern 140, and the other part 121b′ is located outside the second conductive pattern 150. The lightly doped region 125′ may be divided into two parts 125a′ and 125b′, where one part 125a′ is shielded by the second portion 152 of the second conductive pattern 150 extending to the outside of the first conductive pattern 140, and the other part 125b′ is located outside the second conductive pattern 150.

In an embodiment, the second conductive pattern 150 may be made of a metal material. However, the invention is not limited thereto. According to other embodiments, the second conductive pattern 150 may also be made of other conductive materials (for example, alloys, nitrides of metal materials, oxides of metal materials, oxynitrides of metal materials, or stacked layers of metal materials and other conductive materials).

Referring to FIG. 1C and FIG. 1D, the gate G including the first conductive pattern 140 and the second conductive pattern 150 is used as a mask to perform a heavy doping process on the semiconductor layer 120, so that the part 121b′ of the lightly doped region 121′ forms a first heavily doped region 121b, the other part 121a′ of the lightly doped region 121′ forms a first lightly doped region 121a adjacent to the first heavily doped region 121b, and the part 125b′ of the lightly doped region 125′ forms a second heavily doped region 125b, while the other part 125a′ of the lightly doped region 125′ forms a third lightly doped region 125a adjacent to the second heavily doped region 125b.

Referring to FIG. 1D and FIG. 1E, a first terminal 172 and a second terminal 174 are formed to electrically connect the first heavily doped region 121b and the second heavily doped region 125b of the semiconductor layer 120 respectively. At this point, fabrication of a thin film transistor 10 is completed. For example, in the embodiment, an interlayer dielectric layer 160 may be formed on the gate insulating layer 130 and the gate G, and the first terminal 172 and the second terminal 174 are formed on the interlayer dielectric layer 160, where the first terminal 172 is electrically connected to the first heavily doped region 121b of the semiconductor layer 120 through a contact hole 160a of the interlayer dielectric layer 160 and a contact hole 130a of the gate insulating layer 130, and the second terminal 174 is electrically connected to the second heavily doped region 125b of the semiconductor layer 120 through a contact hole 160b of the interlayer dielectric layer 160 and a contact hole 130b of the gate insulating layer 130, but the invention is not limited thereto.

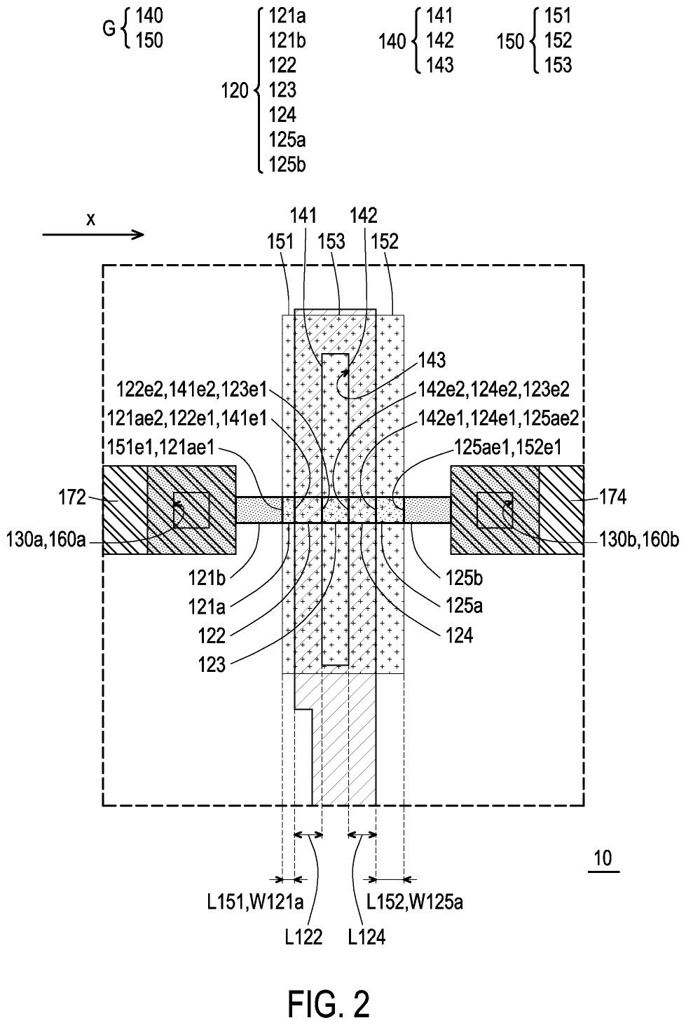

FIG. 2 is a schematic top view of a thin film transistor according to an embodiment of the invention. Referring to FIG. 1E and FIG. 2, the thin film transistor 10 includes the semiconductor layer 120, the gate insulating layer 130, the gate G, the first terminal 172 and the second terminal 174. The semiconductor layer 120 has the first heavily doped region 121b, the first lightly doped region 121a, the first intrinsic region 122, the second lightly doped region 123, the second intrinsic region 124, the third lightly doped region 125a and the second heavily doped region 125b arranged in sequence. The gate insulating layer 130 is disposed on the semiconductor layer 120. The gate G is disposed on the gate insulating layer 130. The first terminal 172 and the second terminal 174 are electrically connected to the first heavily doped region 121b and the second heavily doped region 125b of the semiconductor layer 120 respectively. The first terminal 172 and the second terminal 174 are arranged in a direction x (indicated in FIG. 2). The first intrinsic region 122 and the second intrinsic region 124 respectively have a length L122 (indicated in FIG. 2) and a length L124 (indicated in FIG. 2) in the direction x. A channel length of the thin film transistor 10 is equal to a sum of the length L122 of the first intrinsic region 122 and the length L124 of the second intrinsic region 124. In an embodiment, the lengths L122 and L124 of the first intrinsic region 122 and the second intrinsic region 124 may be optionally equal. However, the invention is not limited thereto. In other embodiments, the lengths L122 and L124 of the first intrinsic region 122 and the second intrinsic region 124 may not be equal.

The gate G includes the first conductive pattern 140 and the second conductive pattern 150. The first conductive pattern 140 of the gate G is disposed on the gate insulating layer 130 and has the first portion 141, the second portion 142 and the opening portion 143. The first portion 141 of the first conductive pattern 140 shields the first intrinsic region 122. The second portion 142 of the first conductive pattern 140 shields the second intrinsic region 124. The opening portion 143 of the first conductive pattern 140 overlaps the second lightly doped region 123.

In an embodiment, two opposite edges 122e1 and 122e2 (indicated in FIG. 2) of the first intrinsic region 122 are respectively aligned with two opposite edges 141e1 and 141e2 (indicated in FIG. 2) of the first portion 141 of the first conductive pattern 140; two opposite edges 124e1 and 124e2 (indicated in FIG. 2) of the second intrinsic region 124 are respectively aligned with two opposite edges 142e1 and 142e2 (indicated in FIG. 2) of the second portion 142 of the first conductive pattern 140; an edge 141e2 (indicated in FIG. 2) of the first portion 141 of the first conductive pattern 140 and an edge 142e2 (indicated in FIG. 2) of the second portion 142 of the first conductive pattern 140 define the opening portion 143, and two opposite edges 123e1 and 123e2 of the second lightly doped region 123 (indicated in FIG. 2) are respectively aligned with the edge 141e2 of the first portion 141 of the first conductive pattern 140 and the edge 142e2 of the second portion 142 of the first conductive pattern 140.

In an embodiment, the opening portion 143 of the first conductive pattern 140 is, for example, a closed type opening. However, the invention is not limited thereto. In other embodiments, the opening portion 143 of the first conductive pattern 140 may also be an open type opening.

The second conductive pattern 150 covers the first conductive pattern 140. In an embodiment, the second conductive pattern 150 directly covers the first conductive pattern 140 and is in contact with the first conductive pattern 140. In particular, the second conductive pattern 150 has the first portion 151 and the second portion 152 extending to the outside of the first conductive pattern 140 and respectively located on two opposite sides of the first conductive pattern 140, where the first portion 151 of the second conductive pattern 150 at least covers a sidewall 141s (indicated in FIG. 1E) of the first portion 141 of the first conductive pattern 140 and shields the first lightly doped region 121a, the second portion 152 of the second conductive pattern 150 at least covers a sidewall 142s (indicated in FIG. 1E) of the second portion 142 of the first conductive pattern 140, and shields the third lightly doped region 125a.

In an embodiment, the second conductive pattern 150 may completely shield the first lightly doped region 121a, the first intrinsic region 122, the second lightly doped region 123, and the second intrinsic region 124 and the third lightly doped region 125a of the semiconductor layer 120.

In an embodiment, the first lightly doped region 121a has a first edge 121ae1 (indicated in FIG. 2) and a second edge 121ae2 (indicated in FIG. 2) opposite to each other, where the first edge 121ae1 of the first lightly doped region 121a is substantially aligned with the edge 151e1 of the first portion 151 of the second conductive pattern 150, and the second edge 121ae2 of the first lightly doped region 121a is substantially aligned with the edge 141e1 of the first portion 141 of the first conductive pattern 140.

In an embodiment, the third lightly doped region 125a has a first edge 125ae1 (indicated in FIG. 2) and a second edge 125ae2 (indicated in FIG. 2) opposite to each other, where the first edge 125ae1 of the third lightly doped region 125a is substantially aligned with the edge 152e1 of the second portion 152 of the second conductive pattern 150, and the second edge 125ae2 of the third lightly doped region 125a is substantially aligned with the edge 142e1 of the second portion 142 of the first conductive pattern 140.

In an embodiment, the first portion 151 of the second conductive pattern 150 has a first length L151 (indicated in FIG. 2) extending beyond the first conductive pattern 140 in the direction x, and the second portion 152 of the second conductive pattern 150 has a second length L152 (indicated in FIG. 2) extending beyond the first conductive pattern 140 in the direction x, and the second length L152 is greater than the first length L151.

In an embodiment, the first terminal 172 and the second terminal 174 are arranged in the direction x, the first lightly doped region 121a has a width W121a (indicated in FIG. 2) in the direction x, the third lightly doped region 125a has a width W125a (indicated in FIG. 2) in the direction x, and the width W125a of the third lightly doped region 125a is greater than the width W121a of the first lightly doped region 121a.

It should be noted that the gate G includes the first conductive pattern 140 and the second conductive pattern 150 covering the first conductive pattern 140, and the second conductive pattern 150 has a first portion 151 and the second portion 152 that exceed the first conductive pattern 140. The thin film transistor 10 uses the gate G including the first conductive pattern 140 and the second conductive pattern 150 to define the first lightly doped region 121a, the first intrinsic region 122, the second lightly doped region 123, the second intrinsic region 124 and the third lightly doped region 125a of the semiconductor layer 120. Therefore, the thin film transistor 10 may have an advantage of short channel length (i.e., high turn-on current). In addition, in an embodiment, since the width W121a of the first lightly doped region 121a is different from the width W125a of the third lightly doped region 125a (i.e., the semiconductor layer 120 of the thin film transistor 10 has an asymmetric design), the thin film transistor 10 further has the advantage of high reliability.

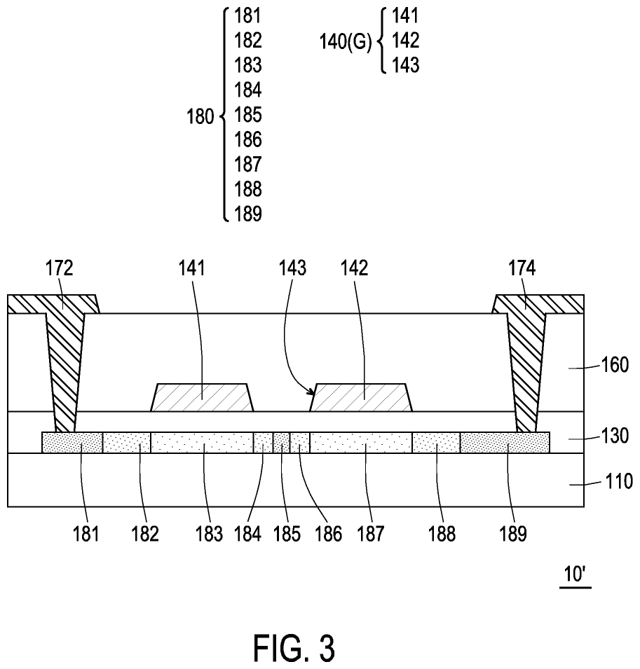

FIG. 3 is a schematic cross-sectional view of a thin film transistor of a comparative example. A thin film transistor 10′ of the comparative example in FIG. 3 is similar to the thin film transistor 10 of the embodiment of FIG. 1E, and a difference there between is that the gate G of the thin film transistor 10′ in the comparative example of FIG. 3 includes the first conductive pattern 140 but does not include the second conductive pattern 150 of FIG. 1E. In addition, a semiconductor layer 180 of the thin film transistor 10′ of the comparative example in FIG. 3 is slightly different from the semiconductor layer 120 of the thin film transistor 10 of the embodiment of FIG. 1E. In detail, the semiconductor layer 180 of the thin film transistor 10′ in FIG. 3 includes a heavily doped region 181, a lightly doped region 182, an intrinsic region 183, a lightly doped region 184, a heavily doped region 185, a lightly doped region 186, an intrinsic region 187, a lightly doped region 188 and a heavily doped region 189 arranged in sequence, where the intrinsic region 183 and the intrinsic region 187 respectively overlap the first portion 141 and the second portion 142 of the gate G, the lightly doped region 184, the heavily doped region 185 and the lightly doped region 186 overlap the opening portion of the gate G, the heavily doped region 181 and the lightly doped region 182 are located outside a first side (for example, a left side) of the gate G, and the lightly doped region 188 and the heavily doped region 189 are located outside a second side (for example, a right side) of the gate G.

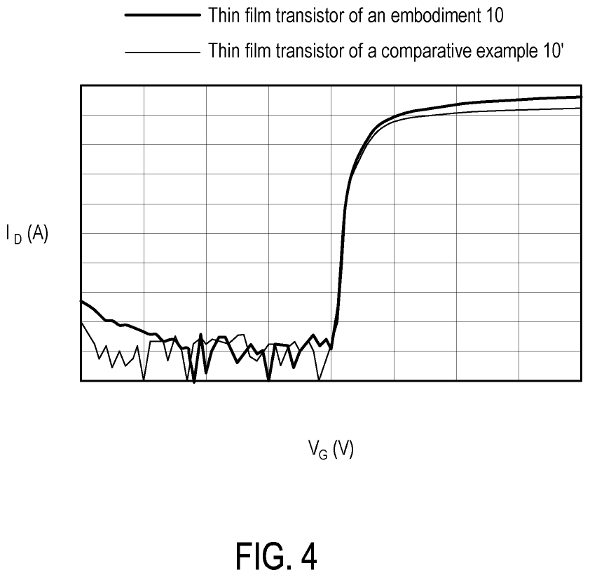

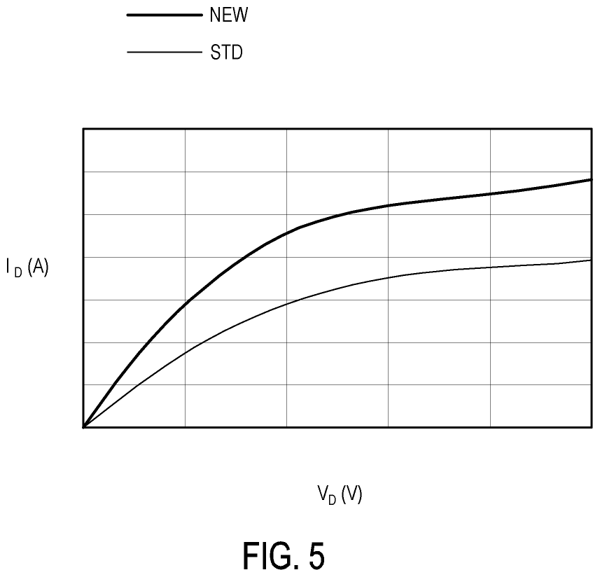

FIG. 4 illustrates relationship curves of a gate voltage V_{G} and a drain current I_{D} of the thin film transistor 10 of the embodiment of the invention and the thin film transistor 10′ of the comparative example. FIG. 5 illustrates relationship curves of a drain voltage V_{D} and a drain current I_{D} of the thin film transistor 10 of the embodiment of the invention and the thin film transistor 10′ of the comparative example. Referring to FIGS. 4 and 5, the drain current I_{D} (i.e., the turn-on current) of the thin film transistor 10 of the embodiment is increased by 40% compared with the drain current I_{D} of the thin film transistor 10′ of the comparative example. This proves that the thin film transistor 10 of the embodiment may indeed significantly increase the turn-on current and achieve the effect of reducing power consumption.

What is claimed is:

1. A thin film transistor, comprising:
a semiconductor layer having a first heavily doped region, a first lightly doped region, a first intrinsic region, a second lightly doped region, a second intrinsic region, a third lightly doped region and a second heavily doped region arranged in sequence;
a gate insulating layer disposed on the semiconductor layer;
a gate comprising:
a first conductive pattern disposed on the gate insulating layer, and having a first portion, a second portion and an opening portion, wherein the first portion of the first conductive pattern shields the first intrinsic region, the second portion of the first conductive pattern shields the second intrinsic region, and the opening portion of the first conductive pattern overlaps the second lightly doped region; and
a second conductive pattern covering the first conductive pattern, wherein the second conductive pattern has a first portion and a second portion extending to an outside of the first conductive pattern and respectively located on two opposite sides of the first conductive pattern, and the first portion and the second portion of the second conductive pattern respectively shield the first lightly doped region and the third lightly doped region; and
a first terminal and a second terminal respectively electrically connected to the first heavily doped region and the second heavily doped region of the semiconductor layer.

2. The thin film transistor according to claim 1, wherein the first portion of the second conductive pattern covers a sidewall of the first portion of the first conductive pattern.

3. The thin film transistor according to claim 2, wherein the second portion of the second conductive pattern covers a sidewall of the second portion of the first conductive pattern.

4. The thin film transistor according to claim 1, wherein the first lightly doped region has a first edge and a second edge opposite to each other, and the first edge of the first lightly doped region is substantially aligned with an edge of the first portion of the second conductive pattern.

5. The thin film transistor according to claim 4, wherein the second edge of the first lightly doped region is substantially aligned with an edge of the first portion of the first conductive pattern.

6. The thin film transistor according to claim 4, wherein the third lightly doped region has a first edge and a second edge opposite to each other, and the first edge of the third lightly doped region is substantially aligned with an edge of the second portion of the second conductive pattern.

7. The thin film transistor according to claim 6, wherein the second edge of the third lightly doped region is substantially aligned with an edge of the second portion of the first conductive pattern.

8. The thin film transistor according to claim 1, wherein the first portion of the second conductive pattern has a first length beyond the first conductive pattern in a direction, the second portion of the second conductive pattern has a second length beyond the first conductive pattern in the direction, and the second length is greater than the first length.

9. The thin film transistor according to claim 1, wherein the first terminal and the second terminal are arranged in a direction, the first lightly doped region has a width in the direction, the third lightly doped region has a width in the direction, and the width of the third lightly doped region is greater than the width of the first lightly doped region.

10. The thin film transistor according to claim 1, wherein the second conductive pattern shields the first lightly doped region, the first intrinsic region, the second lightly doped region, the second intrinsic region and the third lightly doped region.
